(19) United States
(12) Patent Application Publication
(10) Pub. No.: US 2025/0254815 A1
(43) Pub. Date: Aug. 7, 2025

(54) GAME CONSOLE ENDPOINT MANAGEMENT BRIDGE INTERFACE FOR DATACENTER HARDWARE INTEGRATION

(71) Applicant: Sony Interactive Entertainment Inc., Tokyo (JP)

(72) Inventors: Roelof Roderick Colenbrander, Costa Mesa, CA (US); Ritu Gupta, Cupertino, CA (US); Maciej Michal Grochowski, Irvine, CA (US)

(21) Appl. No.: 18/433,271

(22) Filed: Feb. 5, 2024

(51) Int. Cl. H05K 7/14; A63F 13/355; A63F 13/358

(52) U.S. Cl. CPC H05K 7/1492; A63F 13/355; H05K 7/1489; A63F 13/358

(57) ABSTRACT

A server system for installation in a data center is provided, including: a server sled; a backplane disposed in the server sled, said backplane having a plurality of PCIe slots; a plurality of console compute cards mated to the PCIe slots of the backplane, wherein each of the console compute cards includes compute resources substantially similar to compute resources of a game console; wherein the backplane includes a PCIe switch to enable communication with the console compute cards over a PCIe fabric of a server rack in which the server sled is configured to be disposed.

### CROSS-REFERENCE TO RELATED APPLICATIONS

This application is related to U.S. application Ser. No. ______, entitled “GAME CONSOLE DEVELOPMENT HARDWARE HAVING AN ENDPOINT MANAGEMENT BRIDGE INTERFACE,” filed the same day as the present application, and to U.S. application Ser. No. ______, entitled “GAME CONSOLE ENDPOINT MANAGEMENT BRIDGE FOR LOCAL SYSTEM GAME DEVELOPMENT,” filed the same day as the present application, and to U.S. application Ser. No. ______, entitled “METHODS FOR INTEGRATING A GAME CONSOLE CARD TO INTERFACE WITH A HOST SYSTEM,” filed the same day as the present application, the disclosures of which are incorporated by reference in their entirety.

### BACKGROUND OF THE INVENTION

Modern game consoles, such as the PlayStation® 5 video game console, are sophisticated machines capable of providing engaging video game and entertainment experiences. A game console helps to streamline the gaming industry by providing a common platform of standardized resources (e.g. hardware and software) for the development, distribution, and execution of video games. In this manner, game developers can optimize their game development for the game console, and provide consumers with a seamless video game experience devoid of concerns about video game compatibility, optimization or complicated setup with respect to the platform on which the game is run.

A fairly recent development enabled by the proliferation of the Internet is the rise of cloud gaming, in which a video game is executed remotely (e.g. in a remote data center), with gameplay being streamed over the Internet to a user's local client device. More specifically, gaming inputs are transmitted from the client device over the Internet to the cloud executed video game, and the gameplay video generated by the video game is streamed over the Internet to the client device for rendering on a display.

It is in this context that implementations of the disclosure arise.

### SUMMARY OF THE INVENTION

Implementations of the present disclosure include methods, systems and devices for providing a game console endpoint management bridge interface for datacenter hardware integration.

In some implementations, a server system for installation in a data center is provided, including: a server sled; a backplane disposed in the server sled, said backplane having a plurality of PCIe slots; a plurality of console compute cards mated to the PCIe slots of the backplane, wherein each of the console compute cards includes compute resources substantially similar to compute resources of a game console; wherein the backplane includes a PCIe switch to enable communication with the console compute cards over a PCIe fabric of a server rack in which the server sled is configured to be disposed.

In some implementations, the compute resources of each console compute card includes an APU and a Southbridge that are substantially similar to an APU and a Southbridge of the game console.

In some implementations, each console compute card has a PCIe fabric that is separate from the PCIe fabric of the server rack.

In some implementations, each console compute card includes an endpoint management bridge that provides the separation of the PCIe fabric of the console compute card from the PCIe fabric of the server rack.

In some implementations, the backplane is horizontally oriented in the server sled, such that the console compute cards are vertically oriented by mating to the PCIe slots of the backplane.

In some implementations, the console compute cards are configured to communicate over the PCIe fabric of the server rack with a storage server that provides remote storage accessible for the console compute cards.

In some implementations, the storage server is configured to provide video encoding or network connectivity to the console compute cards over the PCIe fabric of the server rack.

In some implementations, the PCIe fabric of the server rack is hosted by the storage server.

In some implementations, the storage server enumerates each of the console compute cards over the PCIe fabric of the server rack.

In some implementations, the console compute cards are configured to natively execute one or more console game titles for cloud gaming, such that gameplay video generated by the execution of said console game titles is streamed over the Internet to respective client devices for gameplay.

In some implementations, server rack assembly for installation in a data center is provided, including: a server rack; a plurality of compute server sleds mounted in the server rack; wherein each compute server sled includes a backplane having a plurality of PCIe slots, and a plurality of console compute cards mated to the PCIe slots of the backplane, wherein each of the console compute cards includes compute resources substantially similar to compute resources of a game console, and wherein the backplane includes a PCIe switch to enable communication with the console compute cards over a PCIe fabric of the server rack.

In some implementations, the compute resources of each console compute card includes an APU and a Southbridge that are substantially similar to an APU and a Southbridge of the game console.

In some implementations, each console compute card has a PCIe fabric that is separate from the PCIe fabric of the server rack.

In some implementations, each console compute card includes an endpoint management bridge that provides the separation of the PCIe fabric of the console compute card from the PCIe fabric of the server rack.

In some implementations, the backplane is horizontally oriented in the compute server sled, such that the console compute cards are vertically oriented by mating to the PCIe slots of the backplane.

In some implementations, the console compute cards are configured to communicate over the PCIe fabric of the server rack with a storage server that provides remote storage accessible for the console compute cards.

In some implementations, the storage server is configured to provide video encoding or network connectivity to the console compute cards over the PCIe fabric of the server rack.

In some implementations, the PCIe fabric of the server rack is hosted by the storage server.

In some implementations, the storage server enumerates each of the console compute cards over the PCIe fabric of the server rack.

In some implementations, the console compute cards are configured to natively execute one or more console game titles for cloud gaming, such that gameplay video generated by the execution of said console game titles is streamed over the Internet to respective client devices for gameplay.

Other aspects and advantages of the disclosure will become apparent from the following detailed description, taken in conjunction with the accompanying drawings, illustrating by way of example the principles of the disclosure.

### BRIEF DESCRIPTION OF DRAWINGS

The disclosure may be better understood by reference to the following description taken in conjunction with the accompanying drawings in which:

FIG. 1 conceptually illustrates a console compute card, in accordance with implementations of the disclosure.

FIG. 2 conceptually illustrates the console compute card 100 integrated into a compute server sled, in accordance with implementations of the disclosure.

FIG. 3 is a conceptual overhead view of a server sled accommodating eight console compute cards, in accordance with implementations of the disclosure.

FIG. 4 conceptually illustrates a server rack having a plurality console compute server sleds, in accordance with implementations of the disclosure.

FIG. 5 conceptually illustrates functionality of the endpoint management bridge 110, in accordance with implementations of the disclosure.

FIG. 6 conceptually illustrates systems for cloud game development and cloud game streaming, in accordance with implementations of the disclosure.

FIG. 7 illustrates components of an example device 700 that can be used to perform aspects of the various embodiments of the present disclosure.

### DETAILED DESCRIPTION OF THE INVENTION

In order to leverage the benefits of console gaming in a cloud gaming setup, one approach is to execute video games on game console hardware in the data center. For example, the game console motherboards (and associated hardware) can be obtained, and server systems can be constructed around the game console motherboards to provide the necessary capabilities for cloud gaming, including handling items such as connectivity, storage, video streaming, power management, cooling, etc. However, because the game console hardware itself has not been optimized for a cloud gaming server environment, this necessitates the development of highly specialized custom componentry, such as custom server chassis, custom power delivery circuit boards and cables, custom mounting brackets and various metal parts, heatsinks, M.2 adapters, etc. Furthermore, a number of hardware interfaces (e.g. PCIe, UART, Ethernet, SATA, HDMI, GPIO, etc.) are required to communicate with the game console for storage, streaming or management, further necessitating a high number of cables for the required connections for each console motherboard, which consumes space and presents additional points of failure. And due to the custom form factor of the console hardware, there may be limitations on spacing and therefore server rack space may not be efficiently utilized.

In view of the above challenges, implementations of the present disclosure provide a console compute card that includes game console componentry in the form factor of a PCIe (Peripheral Component Interconnect Express) card. The console compute card contains important components of a game console, such as an APU (CPU and GPU), DRAM, Southbridge, etc., but is easily integrated into server or PC systems by virtue of its PCIe card form factor. The console compute card has integrated PCIe switch logic that allows for high-speed low-latency communication with the host system, facilitating operations such as storage virtualization and video capture. In some implementations, an integrated endpoint management bridge provides non-transparent bridging between the internal connection fabric of the console compute card and the PCIe fabric of the host system. The endpoint management bridge facilitates consolidation of connectivity over PCIe, so that various management interfaces and even networking functionalities can be conducted over PCIe. This enables simplified server design and requires fewer separate connections and cables.

It will be appreciated that while implementations of the present disclosure are generally described in the form of a PCIe card, other implementations may utilize other busses and interconnect form factors such as CXL, AXI, NVLink and others. It will be appreciated that the concepts described herein with reference to PCIe, can be translated to other such interconnects/fabrics. As non-transparent bridging can be used to provide shared memory coherency between a host (e.g. server host) and a console compute card over PCIe, similar functionality can be provided through analogous mechanisms over alternative busses and interconnect fabrics. For example, functionality for shared memory coherency can be natively built-in to the interconnect in some implementations, or can be provided through particular mirrored endpoint implementations similar those described elsewhere herein.

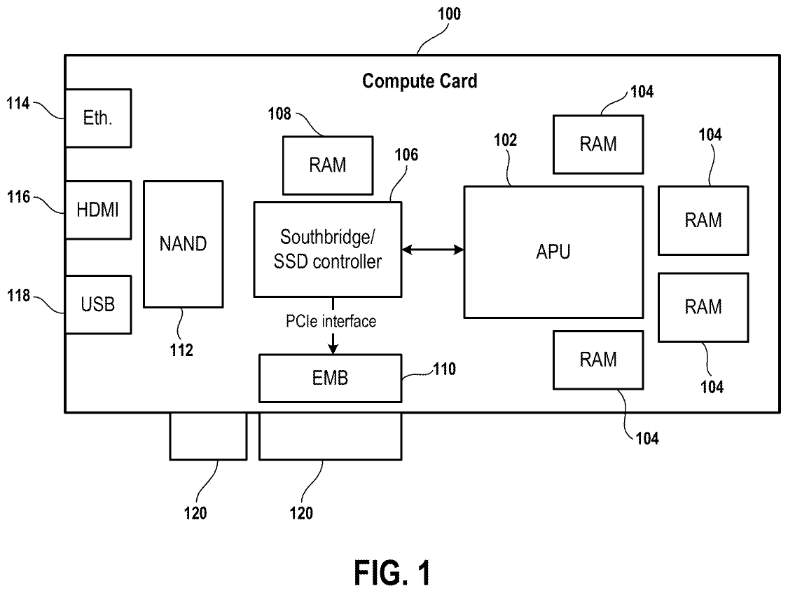

FIG. 1 conceptually illustrates a console compute card, in accordance with implementations of the disclosure.

A console compute card 100 includes hardware of a game console, but in the form factor of a PCIe card. In the illustrated implementation, the console compute card 100 includes an APU 102 (accelerated processing unit) and associated RAM 104. It will be appreciated that an APU consists of a CPU with an integrated GPU. In alternate implementations, a separate CPU and GPU are included in place of the APU 102 in the console compute card 100. The APU 102 is connected to a Southbridge 106, which provides connection to other componentry of the console compute card 100, and may further include storage controller functionality (e.g. SSD controller functionality). In some implementations, the Southbridge 106 is integrated with the APU 102. The Southbridge 106 may have associated RAM 108. In other implementations, the Southbridge 106 (and its functionality) is integrated with the APU 102.

Optionally, the console compute card 100 includes NAND flash memory 112 (or other non-volatile memory), which can be configured to function as a local SSD, mimicking the setup of a game console in which a separate SSD or hard drive is connected as a peripheral device to the game console's motherboard. The NAND flash memory 112 can be connected to the Southbridge 106, and as noted above, the Southbridge 106 can have integrated SSD controller functionality to manage access and read/write operations to the NAND flash memory 112.

Optionally, the console compute card 100 includes additional ports, such as an Ethernet port 114, an HDMI port 116, and a USB port 118. These can provide additional connectivity/networking options for host system setups.

The Southbridge 106 connects over a PCIe interface to an endpoint management bridge 110 (EMB), whose functionality is described in further detail below. In some implementations, the EMB is integrated into the Southbridge 106, which as noted above, can be integrated with the APU 102.

It will be appreciated that the console compute card 100 includes edge connectors 120 for insertion into a PCIe slot of the host system, forming the physical connection of the console compute card 100 to the PCIe bus of the host system. In alternative implementations, other types of PCIe connection form factors can be used to connect the console compute card 100 to a given host system, such as via an external or cabled PCIe connection.

In some implementations, the console compute card 100 is configured for use in a cloud server environment, such as a cloud gaming server or cloud development server.

It will be appreciated that in accordance with implementations of the disclosure, the console compute card 100 includes substantially similar or functionally equivalent resources (e.g. hardware, firmware, operating system, virtualization logic, etc.) to that of a retail game console. That is, the console compute card 100 is at least capable of natively executing the same game titles in the same manner as the retail game console is capable of executing. It will be appreciated that a game console is a special purpose computing device representing a closed system for consumer gaming, as video game titles developed to be compatible to run (natively executable) on the game console are generally not executable on other computing devices (unless special emulation software is used to emulate the hardware and operating system environment of the game console). As a game console is a standalone device, it is not easily integrated with other systems or devices. However, by providing the console compute card 100 of the present disclosure with game console-equivalent resources in the form factor of a PCIe card, integration into server systems and other devices becomes more straightforward and additional collaborative functionality is enabled.

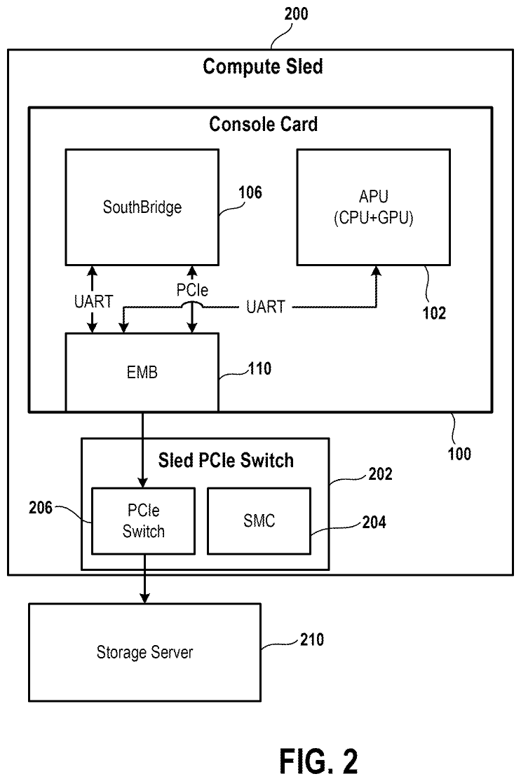

FIG. 2 conceptually illustrates the console compute card 100 integrated into a compute server sled, in accordance with implementations of the disclosure.

In the illustrated implementation, a server sled 200 is provided that includes a sled switch 202. The sled switch 202 is configured to enable connection of one or more of the console compute cards 100 into corresponding PCIe slots. In some implementations, the sled switch 202 includes a sled management controller (SMC) 204 that manages certain operations of the compute sled, such as managing power supply, controlling fan cooling, or in some implementations, accessing certain control or monitoring functionality of the console compute card 100. The sled switch 202 more specifically includes a PCIe switch 206 to which the console compute card 100 is connected (via a PCIe slot).

In some implementations, the PCIe switch 206 is connected to a separate storage server 210, which may be on the same rack as the server sled 200. The storage server 210 provides storage that is accessible to the console compute card 100 over the PCIe fabric via the PCIe switch 206.

While a single console compute card 100 in the server sled 200 is shown, it will be appreciated that in various implementations, there can be any number of console compute cards in a given server sled, provided that adequate power, cooling, connectivity, or other requirements for operation are met.

While the EMB 110 is incorporated in the console compute card 100 in the illustrated implementation, in alternative implementations, the EMB can be incorporated in a separate standalone device. In some implementations, the EMB is defined in the form factor of a separate adapter card connecting between the sled PCIe switch 202 and the Southbridge 106 of the console compute card 100. In some implementations, each console compute card connects through a corresponding standalone EMB adapter card, as each console compute card is provided with similar functionality and management capability enabled by the EMB as described herein. In yet another implementation, a single EMB adapter card is configured to service multiple console compute cards.

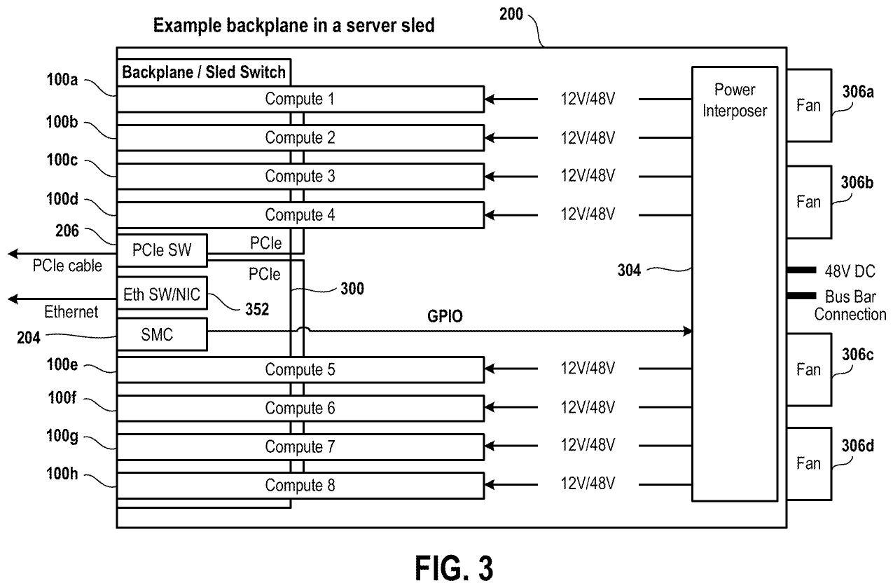

FIG. 3 is a conceptual overhead view of a server sled accommodating eight console compute cards, in accordance with implementations of the disclosure.

In the illustrated implementation, the server sled 200 includes a backplane 300 incorporating the componentry/functionality of the previously described sled switch. The backplane includes at least eight PCIe slots (not shown) which correspondingly accept console compute cards 100a, 100b, 100c, 100d, 100c, 100f, 100g, and 100h as shown. In the illustrated implementation, the console compute cards are vertically slotted into the PCIe slots, which are arranged to provide adequate spacing between the cards for cooling and cable management.

While an example implementation having eight PCIe slots and eight console compute cards is shown and described, it will be appreciated that in other implementations, there can be fewer than eight or more than eight PCIe slots and corresponding console compute cards. By way of example without limitation, in some implementations, there are four or six or more PCIe slots and corresponding console compute cards. In some implementations, the specific number of PCIe slots and corresponding console compute cards is driven by the power consumption of the individual cards and the total power capacity of the server rack. For example, in the case of console compute cards which consume more power, then for a given total power capacity of the server rack, fewer console compute cards can be accommodated by a given server sled.

Each of the console compute cards connects to the PCIe switch 206 to enable communication over the PCIe fabric of the server rack in which the server sled 200 is disposed. In some implementations, the backplane 300 further includes an Ethernet switch or network interface card (NIC) 302 to enable the console compute cards to communicate over an Ethernet network fabric of the server rack.

The console compute cards are powered by a power interposer 304, which in some implementations, provides 12V or 48V power in accordance with the power requirements of the console compute cards. In some implementations, the SMC 204 monitors operation of the power interposer 304, such as power consumption by the console compute cards, over a GPIO connection to the power interposer 304.

The server sled 200 includes a plurality of fans 306a, 306b, 306c, and 306d which provide airflow through the server sled's chassis and thereby provide cooling of the console compute cards. In the illustrated implementation, four fans are provided, with each fan primarily cooling a corresponding pair of the console compute cards. However, in other implementations, there may be more or fewer fans. In some implementations, the fans are powered over a 48V DC bus bar. In some implementations, the fans are responsively controlled by the SMC 204 to provide cooling that is responsive to changes in power consumption and temperature of the console compute cards. In some implementations, each console compute card is capable of consuming about 300 W of power, and therefore, in the illustrated implementation, the fans should be capable of providing sufficient airflow to cool approximately 2.5 kW of power consumption.

A prior cloud gaming server sled implementation utilizing ordinary console hardware could accommodate four console computes in a 2U server sled due to the form factor and connection limitations of the console hardware necessitating a horizontal orientation and layout of console motherboards in the sled chassis. However, by implementation of the present console compute cards arranged in a vertical orientation via PCIe slot connection as described, it is possible to accommodate at least twice the number of console computes in the same 2U server sled space, while still providing sufficient cooling and simplified cable management.

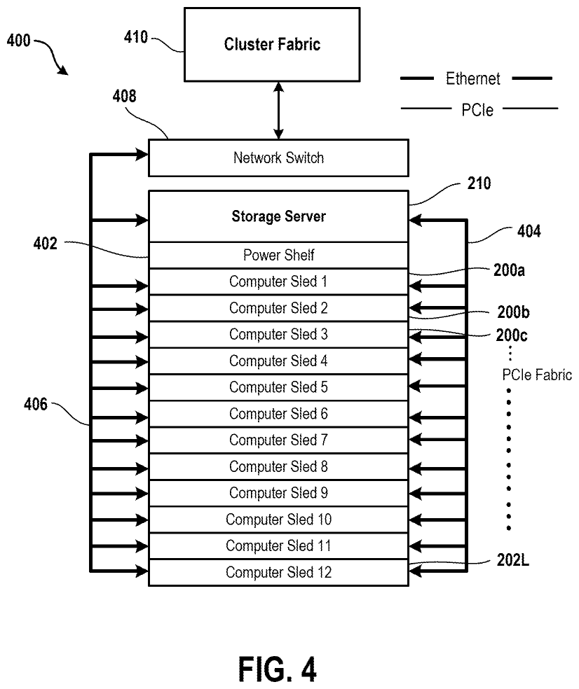

FIG. 4 conceptually illustrates a server rack having a plurality console compute server sleds, in accordance with implementations of the disclosure.

In the illustrated implementation, a server rack 400 for use in a data center is conceptually shown. The server rack 400 includes twelve compute sleds 200a-2001; though in other implementations, there can be more or fewer compute sleds. Each compute sled can be configured as in the previously described server sled 200, and may contain eight or more console compute cards. A power shelf 402 is configured to supply power to each of the components of the server rack 400, including to the power interposers of the compute sleds as previously described.

The server rack 400 further includes a storage server 210, which provides centralized non-volatile storage (e.g. NAND/SSD's, hard drives, etc.) for use by the console compute cards in the compute sleds. It will be appreciated that the compute sleds 200a-1 and the storage server 210 are connected to the PCIe fabric 404 of the server rack, facilitating high-speed data throughput so that non-volatile storage needs of the various compute sleds can be consolidated, managed, and serviced by the storage server 210. In this manner, the console compute cards do not need to possess onboard non-volatile storage for purposes such as storing game titles and related data (e.g. executables, assets, etc.), user save data, etc. as these can be handled by the storage server 210.

While a significant role of the storage server 210 is to provide non-local storage for the console compute cards as described, it will be appreciated that the storage server 210 may include various components for performing other functions as well. For example, in some implementations, the storage server 210 can include various accelerators such as (hardware/software) video encoders, GPUs, FPGAs, network adapters or other devices. Video encoders, for example, could provide extra video encoder capacity or provide a way to add the functionality of newer video codecs as they emerge over time. In a cloud gaming context, for example, the storage server may function as a cloud gaming server expected to last 5-10 years, and in that time frame new codecs may emerge. The storage server could be upgraded with newer hardware over time to enable support for such newer codecs to be added after the storage server is placed in service. It will be appreciated that data from the console compute cards can be shared over the PCIe fabric with these cards. This could be done directly or with the help of software (e.g. drivers) on both the storage server and a given console card.

Similarly, in some implementations, the storage server can include a (high-speed) network card, and the enabled high-speed network connectivity of the storage server could be shared over PCIe with the console compute cards. For example, virtual networking could be implemented over the PCIe fabric between the console compute cards and the storage server. This can help to limit the number of cables needed for connection to the console compute cards, and may provide even better performance than a network adapter integrated into the console compute card. Again, as the network card of the storage server can be upgraded over time, so the network connectivity made available to the console compute cards can be improved as well.

In the illustrated implementation, the compute sleds 200a-1 and the storage server 210 are further connected to an Ethernet network fabric 406 of the server rack 400 that extends to a network switch 408 that services the server rack 400. The network switch 408 is further connected to the cluster fabric 410 of the data center of which the server rack is a part. In this manner, the console compute cards of the compute sleds are addressable over Ethernet, via standard networking protocols.

It will be appreciated that the console compute cards of the present disclosure can have many use cases within gaming sessions and outside. Within a gaming context, a user experience may span one or more console compute cards. For example, a single player game for a single user may use multiple cards. Or a multiplayer game may span multiple cards on behalf of multiple users.

Other use cases include AI/ML workloads, 3D rendering workloads, generic compute workloads, etc. These can be performed during ‘darktime’ hours when the hardware is not being used for gaming purposes, and may be repurposed. AI workloads may require multiple cards working together sharing data (e.g. passing results from one card to another or sharing a common data set (e.g. from a storage server)). An AI workload may also be in support of a gaming workload. For example, one console compute card may execute the game session whereas another console compute card may execute an AI workload to provide AI services for the game session. Such use cases may utilize the PCIe fabric for high-speed, low-latency data sharing.

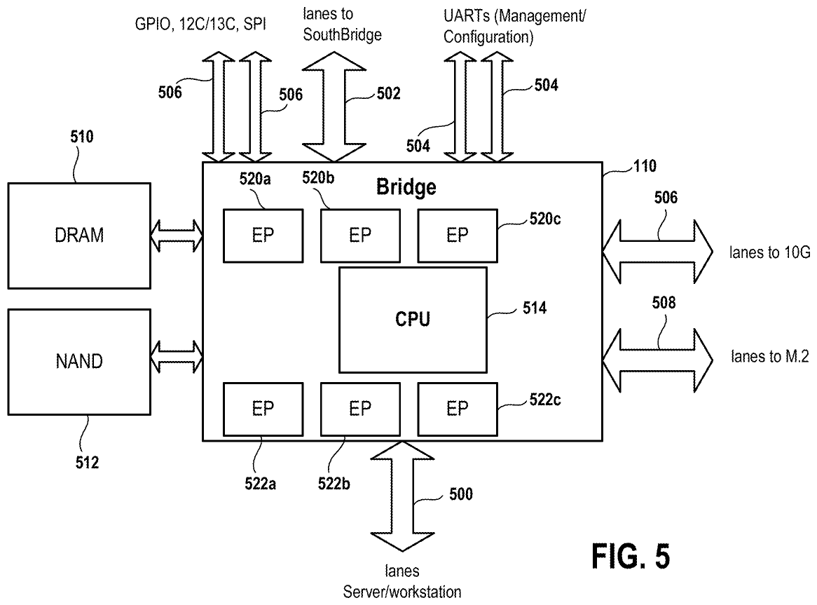

FIG. 5 conceptually illustrates functionality of the endpoint management bridge 110, in accordance with implementations of the disclosure.

The endpoint management bridge (EMB) 110 provides a non-transparent bridging functionality between the console compute card 100 and the host system in which the card is disposed. The EMB 110 enables the console compute card 100 to interface with the PCIe fabric of the host system while maintaining separation of the communications fabric of the console compute card 100 (which can itself include a PCIe fabric). Furthermore, the EMB 110 enables other communications protocols to be virtualized over PCIe, so that most if not all communication with the console compute card 100 is effected over PCIe, thereby simplifying connectivity to the console compute card 100.

In the illustrated implementation, the EMB 110 is configured to have an external connection 500 over PCIe to the host system (e.g. server/workstation).

Optionally, the EMB 110 is configured to have additional internal connections to onboard devices over PCIe. For example, an internal connection 506 is provided over PCIe to networking hardware of the console computer card (e.g. 10G NIC). Optionally, the EMB 110 is configured to have an internal connection 508 over PCIe to an M.2 storage device of the console compute card. In some implementations, in order to provide sufficient PCIe lanes to support such connections, the EMB 110 can include a PCIe switch (not shown).

The EMB 110 is further configured to have an internal connection 502 over PCIe (internal PCIe fabric of the console compute card 100) to the Southbridge 106 of the console compute card 100. Optionally, the EMB 110 is configured to have one or more internal connections 504 facilitating communication over UART. Optionally, the EMB 110 is configured to have one or more internal connections 506 facilitating communication over other protocols, such as GPIO, I2C/I3C, SPI, etc.

In some implementations, the EMB 110 is connected to DRAM 510 and/or NAND 512, providing volatile and/or non-volatile storage for access by the EMB 110.

The EMB 110 includes a CPU 514 that provides management of console operations such as power on/off, reboot, diagnostics, firmware updates, debug, etc. The CPU may also handle configuration of endpoints, which are described below.

In further implementations, the CPU 514, DRAM 510, NAND 512, and/or at least some of their functionality, can be externally provided (e.g. via the PCIe connection to the console compute card or another connection).

The EMB 110 further includes a plurality of endpoints that define destination targets for communications originating from within the console compute card 100, or from other entities such as the host system in which the console compute card 100 is disposed, other PCIe devices connected to the host system, other devices networked to the host system (e.g. networked storage device), etc. To this end, in some implementations, the endpoints are one-sided in the sense that they are defined to be visible to either the entities within the console compute card 100 that communicate with the EMB 110, or those of the host system that communicate with the EMB 110, but not both. Thus, some endpoints are internally facing endpoints exposed to the internal communications fabric of the console compute card 100 (but not the communications fabric of the host system), while other endpoints are externally facing endpoints and exposed to the communications fabric of the host system (but not the internal communications fabric of the console compute card 100). In the illustrated implementation, endpoints 520a, 520b, and 520c are internally facing endpoints, accessed by componentry of the console compute card 100 in communication with the EMB 110, but not accessible by the host system. Whereas, endpoints 522a, 522b, and 522c are externally facing endpoints accessed by the host system, but not accessible by the internal components of the console compute card 100.

In some instances, endpoints are mirrored or defined in corresponding pairs, so that functionalities associated with the mirrored endpoints can be effected from either side to the other, that is, from the host system to the console compute card 100, or from the console compute card 100 to the host system. This is accomplished by implementing logic for translation of operations between mirrored endpoints.

By implementing endpoints in this way, conflicts that might otherwise arise from having two “host”-type entities interfacing with each other (e.g. the APU of the console compute card 100 and the CPU of the host system) are avoided. The endpoints of each side are independently enumerated, for example, over the respective PCIe fabrics of the console compute card 100 and host system, and separation between the systems is maintained. In the illustrated implementation, the APU 102 of the console compute card 100 enumerates the endpoints 520a, 520b, and 520c, whereas the CPU of the host system enumerates the endpoints 522a, 522b, and 522c. Furthermore, the custom endpoints and translation logic of the present implementations enable different interfaces/protocols (including non-PCIe interfaces/protocols) which are native to the console compute card 100 to be effectively accessible over PCIe, so that additional connections for such interfaces are not required as they can be accessed through the PCIe bus of the host system. Thus, console compute I/O functionality does not need to be modified, as the native operating interface conditions are effectively maintained from the standpoint of components of the console compute card 100 that communicate with the EMB 110. Put another way, the endpoints can be configured to emulate interfaces on the console compute side, so that the console compute card 100 can operate the same interface specs internally as the regular game console would operate. This provides consistency of the internal interface operating environment of the console compute card 100, which is important for purposes of providing consistency in game development and execution.

By way of example without limitation, there can be many endpoints implemented to enable communications of data between the console compute card 100 and the host system in which the console compute card 100 is disposed, which can be mirrored as discussed above. Several non-limiting examples are described below.

In some implementations, an internally facing NVMe device endpoint provides efficient emulation of an NVMe drive storage so that the APU 102 (or other component of the console compute card 100) can access the NVMe device endpoint as if it were an actual local NVMe storage device. A corresponding externally facing storage endpoint would map to a storage device of the host system, and operations would be translated between the internal NVMe device endpoint and the external storage endpoint, enabling the console compute card 100 to access storage of the host system while presenting such access in the form of an NVMe device.

In some implementations, peer-to-peer endpoints can be defined to allow for data movement between multiple nodes, including amongst multiple console compute cards installed in a given host system and the host system itself. Such P2P endpoints can be used to enable virtual networking, video frame capturing, or P2P communication between multiple console compute nodes/cards (e.g. for AI workloads, etc.). Generally speaking, the P2P endpoints enable access to the memory address spaces of the console compute cards and the host system, so that data can be moved efficiently amongst the various nodes.

In some implementations, a management endpoint is defined to enable features such as configuration of the Southbridge endpoint, debug, Nandless boot (booting of the compute node without need of NAND on the compute node), firmware update of the Southbridge chip, NVS/QA flag state management, etc.

In some implementations, an SMBUS sideband interface is provided to the management endpoint. It will be appreciated that the PCIe slot can provide an SMBUS interface, which can be leveraged to provide the sideband interface. This can be useful for enabling firmware updates or for disaster recovery operations. Such a sideband interface can be configured to access control registers (e.g. for reboot/power cycling).

In some implementations, an EMC management interface endpoint is implemented to provide the ability to send commands to the Southbridge. This can be used for control and status information purposes, such as power on/off/reboot, physical telemetry (e.g. temperature), power status, version information, diagnostics, etc.

In some implementations, UART endpoints are implemented to enable exposure of UART communications over PCIe (e.g. UART communications from the APU). Such UART endpoints can be useful for enabling serial console access through the APU.

In some implementations, the endpoints are PCIe bus powered so as to stay online regardless of the power status of the console compute card 100. This enables the endpoints to stay online during reboot of the console compute card 100 to avoid PCIe hotplugs/unplugs on the host system (e.g. preserving continuity with storage/management server).

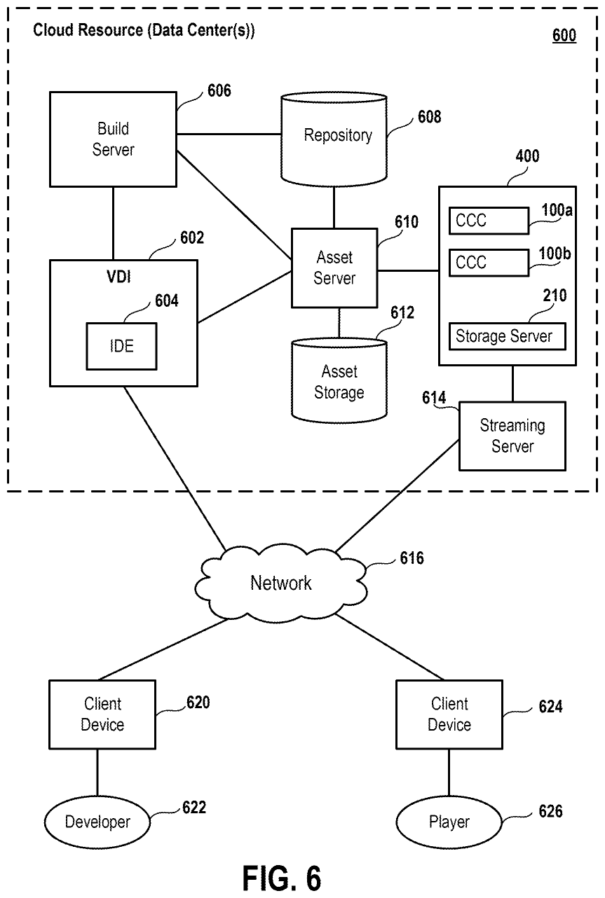

FIG. 6 conceptually illustrates systems for cloud game development and cloud game streaming, in accordance with implementations of the disclosure.

In the illustrated implementation, a cloud resource 600 having cloud processing and cloud storage resources is provided. In various implementations, the illustrated systems can be implemented in one or more data centers, connected over the Internet. It will be appreciated that the console compute cards can be used to enable cloud game streaming of console-based video games. For example, the server rack 400 can be implemented in a data center, and a given console compute card 100a can be assigned to a player 626 and client device 624 for gameplay of a given console video game title. The console compute card 100a will be loaded with the video game title, and gameplay will be streamed over network 616 (including the Internet) to the player's client device 624. In some implementations, a streaming server 614 is implemented to manage video streaming to the client device 624, for example, to optimize the video stream for network conditions, the player's hardware capabilities, etc.

In some implementations, a cloud-based game development platform is enabled by using the console compute cards in conjunction with game development systems. For example, a virtual desktop infrastructure 602 can be implemented that allows a developer 622 operating their client device 620 to access over network 616 a virtual desktop providing cloud-hosted tools for game development, such as an integrated development environment 604 or other development software (e.g. 3D rendering/animation software, etc.). An asset server 610 manages access to an asset storage 612 containing game assets such as textures, rigs, animations, audio, etc. A build server 606 manages access to various builds of video games, stored to a repository 608. The build server 606 can manage access to source code files, and compile source code into executables for deployment onto the console compute cards.

When a given executable build of a video game is executed by a console compute card, then the gameplay of the game build can be cloud streamed as previously described. For example, the player 626 may be a quality assurance (QA) tester or alpha/beta tester involved in supporting the development of the video game. In this manner, a cloud environment for end-to-end game development of console-based games is enabled, whereby game assets and builds are developed in the cloud, and testing on console-equivalent hardware is also cloud-based. This enables development teams and individuals, including software developers, artists, QA testers, project managers, etc. to engage and collaborate in game development activities remotely.

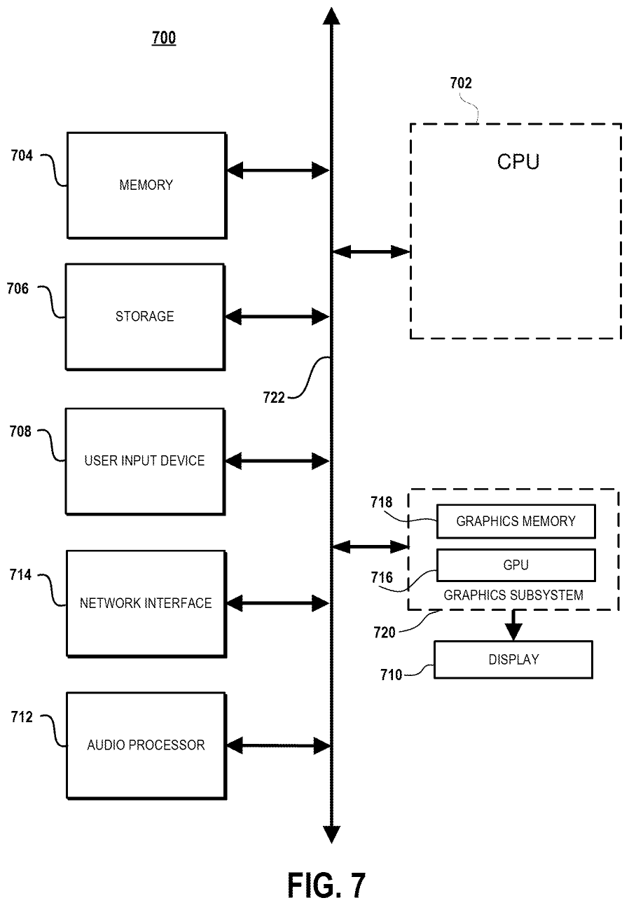

FIG. 7 illustrates components of an example device 700 that can be used to perform aspects of the various embodiments of the present disclosure. This block diagram illustrates a device 700 that can incorporate or can be a personal computer, video game console, personal digital assistant, a server or other digital device, suitable for practicing an embodiment of the disclosure. Device 700 includes a central processing unit (CPU) 702 for running software applications and optionally an operating system. CPU 702 may be comprised of one or more homogeneous or heterogeneous processing cores. For example, CPU 702 is one or more general-purpose microprocessors having one or more processing cores. Further embodiments can be implemented using one or more CPUs with microprocessor architectures specifically adapted for highly parallel and computationally intensive applications, such as processing operations of interpreting a query, identifying contextually relevant resources, and implementing and rendering the contextually relevant resources in a video game immediately. Device 700 may be a localized to a player playing a game segment (e.g., game console), or remote from the player (e.g., back-end server processor), or one of many servers using virtualization in a game cloud system for remote streaming of gameplay to clients.

Memory 704 stores applications and data for use by the CPU 702. Storage 706 provides non-volatile storage and other computer readable media for applications and data and may include fixed disk drives, removable disk drives, flash memory devices, and CD-ROM, DVD-ROM, Blu-ray, HD-DVD, or other optical storage devices, as well as signal transmission and storage media. User input devices 708 communicate user inputs from one or more users to device 700, examples of which may include keyboards, mice, joysticks, touch pads, touch screens, still or video recorders/cameras, tracking devices for recognizing gestures, and/or microphones. Network interface 714 allows device 700 to communicate with other computer systems via an electronic communications network, and may include wired or wireless communication over local area networks and wide area networks such as the internet. An audio processor 712 is adapted to generate analog or digital audio output from instructions and/or data provided by the CPU 702, memory 704, and/or storage 706. The components of device 700, including CPU 702, memory 704, data storage 706, user input devices 708, network interface 710, and audio processor 712 are connected via one or more data buses 722.

A graphics subsystem 720 is further connected with data bus 722 and the components of the device 700. The graphics subsystem 720 includes a graphics processing unit (GPU) 716 and graphics memory 718. Graphics memory 718 includes a display memory (e.g., a frame buffer) used for storing pixel data for each pixel of an output image. Graphics memory 718 can be integrated in the same device as GPU 708, connected as a separate device with GPU 716, and/or implemented within memory 704. Pixel data can be provided to graphics memory 718 directly from the CPU 702. Alternatively, CPU 702 provides the GPU 716 with data and/or instructions defining the desired output images, from which the GPU 716 generates the pixel data of one or more output images. The data and/or instructions defining the desired output images can be stored in memory 704 and/or graphics memory 718. In an embodiment, the GPU 716 includes 3D rendering capabilities for generating pixel data for output images from instructions and data defining the geometry, lighting, shading, texturing, motion, and/or camera parameters for a scene. The GPU 716 can further include one or more programmable execution units capable of executing shader programs.

The graphics subsystem 714 periodically outputs pixel data for an image from graphics memory 718 to be displayed on display device 710. Display device 710 can be any device capable of displaying visual information in response to a signal from the device 700, including CRT, LCD, plasma, and OLED displays. Device 700 can provide the display device 710 with an analog or digital signal, for example.

It should be noted, that access services, such as providing access to games of the current embodiments, delivered over a wide geographical area often use cloud computing. Cloud computing is a style of computing in which dynamically scalable and often virtualized resources are provided as a service over the Internet. Users do not need to be an expert in the technology infrastructure in the “cloud” that supports them. Cloud computing can be divided into different services, such as Infrastructure as a Service (IaaS), Platform as a Service (PaaS), and Software as a Service (SaaS). Cloud computing services often provide common applications, such as video games, online that are accessed from a web browser, while the software and data are stored on the servers in the cloud. The term cloud is used as a metaphor for the Internet, based on how the Internet is depicted in computer network diagrams and is an abstraction for the complex infrastructure it conceals.

A game server may be used to perform the operations of the durational information platform for video game players, in some embodiments. Most video games played over the Internet operate via a connection to the game server. Typically, games use a dedicated server application that collects data from players and distributes it to other players. In other embodiments, the video game may be executed by a distributed game engine. In these embodiments, the distributed game engine may be executed on a plurality of processing entities (PEs) such that each PE executes a functional segment of a given game engine that the video game runs on. Each processing entity is seen by the game engine as simply a compute node. Game engines typically perform an array of functionally diverse operations to execute a video game application along with additional services that a user experiences. For example, game engines implement game logic, perform game calculations, physics, geometry transformations, rendering, lighting, shading, audio, as well as additional in-game or game-related services. Additional services may include, for example, messaging, social utilities, audio communication, game play replay functions, help function, etc. While game engines may sometimes be executed on an operating system virtualized by a hypervisor of a particular server, in other embodiments, the game engine itself is distributed among a plurality of processing entities, each of which may reside on different server units of a data center.

According to this embodiment, the respective processing entities for performing the operations may be a server unit, a virtual machine, or a container, depending on the needs of each game engine segment. For example, if a game engine segment is responsible for camera transformations, that particular game engine segment may be provisioned with a virtual machine associated with a graphics processing unit (GPU) since it will be doing a large number of relatively simple mathematical operations (e.g., matrix transformations). Other game engine segments that require fewer but more complex operations may be provisioned with a processing entity associated with one or more higher power central processing units (CPUs).

By distributing the game engine, the game engine is provided with elastic computing properties that are not bound by the capabilities of a physical server unit. Instead, the game engine, when needed, is provisioned with more or fewer compute nodes to meet the demands of the video game. From the perspective of the video game and a video game player, the game engine being distributed across multiple compute nodes is indistinguishable from a non-distributed game engine executed on a single processing entity, because a game engine manager or supervisor distributes the workload and integrates the results seamlessly to provide video game output components for the end user.

Users access the remote services with client devices, which include at least a CPU, a display and I/O. The client device can be a PC, a mobile phone, a netbook, a PDA, etc. In one embodiment, the network executing on the game server recognizes the type of device used by the client and adjusts the communication method employed. In other cases, client devices use a standard communications method, such as html, to access the application on the game server over the internet. It should be appreciated that a given video game or gaming application may be developed for a specific platform and a specific associated controller device. However, when such a game is made available via a game cloud system as presented herein, the user may be accessing the video game with a different controller device. For example, a game might have been developed for a game console and its associated controller, whereas the user might be accessing a cloud-based version of the game from a personal computer utilizing a keyboard and mouse. In such a scenario, the input parameter configuration can define a mapping from inputs which can be generated by the user's available controller device (in this case, a keyboard and mouse) to inputs which are acceptable for the execution of the video game.

In another example, a user may access the cloud gaming system via a tablet computing device, a touchscreen smartphone, or other touchscreen driven device. In this case, the client device and the controller device are integrated together in the same device, with inputs being provided by way of detected touchscreen inputs/gestures. For such a device, the input parameter configuration may define particular touchscreen inputs corresponding to game inputs for the video game. For example, buttons, a directional pad, or other types of input elements might be displayed or overlaid during running of the video game to indicate locations on the touchscreen that the user can touch to generate a game input. Gestures such as swipes in particular directions or specific touch motions may also be detected as game inputs. In one embodiment, a tutorial can be provided to the user indicating how to provide input via the touchscreen for gameplay, e.g., prior to beginning gameplay of the video game, so as to acclimate the user to the operation of the controls on the touchscreen.

In some embodiments, the client device serves as the connection point for a controller device. That is, the controller device communicates via a wireless or wired connection with the client device to transmit inputs from the controller device to the client device. The client device may in turn process these inputs and then transmit input data to the cloud game server via a network (e.g., accessed via a local networking device such as a router). However, in other embodiments, the controller can itself be a networked device, with the ability to communicate inputs directly via the network to the cloud game server, without being required to communicate such inputs through the client device first. For example, the controller might connect to a local networking device (such as the aforementioned router) to send to and receive data from the cloud game server. Thus, while the client device may still be required to receive video output from the cloud-based video game and render it on a local display, input latency can be reduced by allowing the controller to send inputs directly over the network to the cloud game server, bypassing the client device.

In one embodiment, a networked controller and client device can be configured to send certain types of inputs directly from the controller to the cloud game server, and other types of inputs via the client device. For example, inputs whose detection does not depend on any additional hardware or processing apart from the controller itself can be sent directly from the controller to the cloud game server via the network, bypassing the client device. Such inputs may include button inputs, joystick inputs, embedded motion detection inputs (e.g., accelerometer, magnetometer, gyroscope), etc. However, inputs that utilize additional hardware or require processing by the client device can be sent by the client device to the cloud game server. These might include captured video or audio from the game environment that may be processed by the client device before sending to the cloud game server. Additionally, inputs from motion detection hardware of the controller might be processed by the client device in conjunction with captured video to detect the position and motion of the controller, which would subsequently be communicated by the client device to the cloud game server. It should be appreciated that the controller device in accordance with various embodiments may also receive data (e.g., feedback data) from the client device or directly from the cloud gaming server.

In one embodiment, the various technical examples can be implemented using a virtual environment via a head-mounted display (HMD). An HMD may also be referred to as a virtual reality (VR) headset. As used herein, the term “virtual reality” (VR) generally refers to user interaction with a virtual space/environment that involves viewing the virtual space through an HMD (or VR headset) in a manner that is responsive in real-time to the movements of the HMD (as controlled by the user) to provide the sensation to the user of being in the virtual space or metaverse. For example, the user may see a three-dimensional (3D) view of the virtual space when facing in a given direction, and when the user turns to a side and thereby turns the HMD likewise, then the view to that side in the virtual space is rendered on the HMD. An HMD can be worn in a manner similar to glasses, goggles, or a helmet, and is configured to display a video game or other metaverse content to the user. The HMD can provide a very immersive experience to the user by virtue of its provision of display mechanisms in close proximity to the user's eyes. Thus, the HMD can provide display regions to each of the user's eyes which occupy large portions or even the entirety of the field of view of the user, and may also provide viewing with three-dimensional depth and perspective.

In one embodiment, the HMD may include a gaze tracking camera that is configured to capture images of the eyes of the user while the user interacts with the VR scenes. The gaze information captured by the gaze tracking camera(s) may include information related to the gaze direction of the user and the specific virtual objects and content items in the VR scene that the user is focused on or is interested in interacting with. Accordingly, based on the gaze direction of the user, the system may detect specific virtual objects and content items that may be of potential focus to the user where the user has an interest in interacting and engaging with, e.g., game characters, game objects, game items, etc.

In some embodiments, the HMD may include an externally facing camera(s) that is configured to capture images of the real-world space of the user such as the body movements of the user and any real-world objects that may be located in the real-world space. In some embodiments, the images captured by the externally facing camera can be analyzed to determine the location/orientation of the real-world objects relative to the HMD. Using the known location/orientation of the HMD the real-world objects, and inertial sensor data from the, the gestures and movements of the user can be continuously monitored and tracked during the user's interaction with the VR scenes. For example, while interacting with the scenes in the game, the user may make various gestures such as pointing and walking toward a particular content item in the scene. In one embodiment, the gestures can be tracked and processed by the system to generate a prediction of interaction with the particular content item in the game scene. In some embodiments, machine learning may be used to facilitate or assist in said prediction.

During HMD use, various kinds of single-handed, as well as two-handed controllers can be used. In some implementations, the controllers themselves can be tracked by tracking lights included in the controllers, or tracking of shapes, sensors, and inertial data associated with the controllers. Using these various types of controllers, or even simply hand gestures that are made and captured by one or more cameras, it is possible to interface, control, maneuver, interact with, and participate in the virtual reality environment or metaverse rendered on an HMD. In some cases, the HMD can be wirelessly connected to a cloud computing and gaming system over a network. In one embodiment, the cloud computing and gaming system maintains and executes the video game being played by the user. In some embodiments, the cloud computing and gaming system is configured to receive inputs from the HMD and the interface objects over the network. The cloud computing and gaming system is configured to process the inputs to affect the game state of the executing video game. The output from the executing video game, such as video data, audio data, and haptic feedback data, is transmitted to the HMD and the interface objects. In other implementations, the HMD may communicate with the cloud computing and gaming system wirelessly through alternative mechanisms or channels such as a cellular network.

Additionally, though implementations in the present disclosure may be described with reference to a head-mounted display, it will be appreciated that in other implementations, non-head mounted displays may be substituted, including without limitation, portable device screens (e.g. tablet, smartphone, laptop, etc.) or any other type of display that can be configured to render video and/or provide for display of an interactive scene or virtual environment in accordance with the present implementations. It should be understood that the various embodiments defined herein may be combined or assembled into specific implementations using the various features disclosed herein. Thus, the examples provided are just some possible examples, without limitation to the various implementations that are possible by combining the various elements to define many more implementations. In some examples, some implementations may include fewer elements, without departing from the spirit of the disclosed or equivalent implementations.

Embodiments of the present disclosure may be practiced with various computer system configurations including hand-held devices, microprocessor systems, microprocessor-based or programmable consumer electronics, minicomputers, mainframe computers and the like. Embodiments of the present disclosure can also be practiced in distributed computing environments where tasks are performed by remote processing devices that are linked through a wire-based or wireless network.

Although the method operations were described in a specific order, it should be understood that other housekeeping operations may be performed in between operations, or operations may be adjusted so that they occur at slightly different times or may be distributed in a system which allows the occurrence of the processing operations at various intervals associated with the processing, as long as the processing of the telemetry and game state data for generating modified game states and are performed in the desired way.

One or more embodiments can also be fabricated as computer readable code on a computer readable medium. The computer readable medium is any data storage device that can store data, which can be thereafter be read by a computer system. Examples of the computer readable medium include hard drives, network attached storage (NAS), read-only memory, random-access memory, CD-ROMs, CD-Rs, CD-RWs, magnetic tapes and other optical and non-optical data storage devices. The computer readable medium can include computer readable tangible medium distributed over a network-coupled computer system so that the computer readable code is stored and executed in a distributed fashion.

In one embodiment, the video game is executed either locally on a gaming machine, a personal computer, or on a server. In some cases, the video game is executed by one or more servers of a data center. When the video game is executed, some instances of the video game may be a simulation of the video game. For example, the video game may be executed by an environment or server that generates a simulation of the video game. The simulation, on some embodiments, is an instance of the video game. In other embodiments, the simulation maybe produced by an emulator. In either case, if the video game is represented as a simulation, that simulation is capable of being executed to render interactive content that can be interactively streamed, executed, and/or controlled by user input.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within the scope and equivalents of the appended claims.

1. A server system for installation in a data center, comprising:
a server sled;
a backplane disposed in the server sled, said backplane having a plurality of PCIe slots;
a plurality of console compute cards mated to the PCIe slots of the backplane, wherein each of the console compute cards includes compute resources substantially similar to compute resources of a game console;
wherein the backplane includes a PCIe switch to enable communication with the console compute cards over a PCIe fabric of a server rack in which the server sled is configured to be disposed.

2. The server system of claim 1, wherein the compute resources of each console compute card includes an APU and a Southbridge that are substantially similar to an APU and a Southbridge of the game console.

3. The server system of claim 1, wherein each console compute card has a PCIe fabric that is separate from the PCIe fabric of the server rack.

4. The server system of claim 3, wherein each console compute card includes an endpoint management bridge that provides the separation of the PCIe fabric of the console compute card from the PCIe fabric of the server rack.

5. The server system of claim 1, wherein the backplane is horizontally oriented in the server sled, such that the console compute cards are vertically oriented by mating to the PCIe slots of the backplane.

6. The server system of claim 1, wherein the console compute cards are configured to communicate over the PCIe fabric of the server rack with a storage server that provides remote storage accessible for the console compute cards.

7. The server system of claim 6, wherein the storage server is configured to provide video encoding or network connectivity to the console compute cards over the PCIe fabric of the server rack.

8. The server system of claim 7, wherein the PCIe fabric of the server rack is hosted by the storage server.

9. The server system of claim 8, wherein the storage server enumerates each of the console compute cards over the PCIe fabric of the server rack.

10. The server system of claim 1, wherein the console compute cards are configured to natively execute one or more console game titles for cloud gaming, such that gameplay video generated by the execution of said console game titles is streamed over the Internet to respective client devices for gameplay.

11. A server rack assembly for installation in a data center, comprising:
a server rack;
a plurality of compute server sleds mounted in the server rack;
wherein each compute server sled includes a backplane having a plurality of PCIe slots, and a plurality of console compute cards mated to the PCIe slots of the backplane,
wherein each of the console compute cards includes compute resources substantially similar to compute resources of a game console, and
wherein the backplane includes a PCIe switch to enable communication with the console compute cards over a PCIe fabric of the server rack.

12. The server rack assembly of claim 11, wherein the compute resources of each console compute card includes an APU and a Southbridge that are substantially similar to an APU and a Southbridge of the game console.

13. The server rack assembly of claim 11, wherein each console compute card has a PCIe fabric that is separate from the PCIe fabric of the server rack.

14. The server rack assembly of claim 13, wherein each console compute card includes an endpoint management bridge that provides the separation of the PCIe fabric of the console compute card from the PCIe fabric of the server rack.

15. The server rack assembly of claim 11, wherein the backplane is horizontally oriented in the compute server sled, such that the console compute cards are vertically oriented by mating to the PCIe slots of the backplane.

16. The server rack assembly of claim 11, wherein the console compute cards are configured to communicate over the PCIe fabric of the server rack with a storage server that provides remote storage accessible for the console compute cards.

17. The server rack assembly of claim 16, wherein the storage server is configured to provide video encoding or network connectivity to the console compute cards over the PCIe fabric of the server rack.

18. The server rack assembly of claim 17, wherein the PCIe fabric of the server rack is hosted by the storage server.

19. The server rack assembly of claim 18, wherein the storage server enumerates each of the console compute cards over the PCIe fabric of the server rack.

20. The server rack assembly of claim 11, wherein the console compute cards are configured to natively execute one or more console game titles for cloud gaming, such that gameplay video generated by the execution of said console game titles is streamed over the Internet to respective client devices for gameplay.
